(19) United States
(12) Patent Application Publication
(10) Pub. No.: US 2025/0202145 A1
(43) Pub. Date: Jun. 19, 2025

(54) HIGH-VOLTAGE ANTI-CONDENSATION INNTERCONNECTION SYSTEM AND CONNECTORS AND CIRCUIT BOARDS THEREOF

(71) Applicant: Amphenol Aorora Technology, Huizhou (CN)

(72) Inventors: Xiaohong Zhu, Huizhou (CN); Shan Huang, Huizhou (CN); Hancheng Chen, Huizhou (CN)

(73) Assignee: Amphenol Aorora Technology, Huizhou (CN)

(21) Appl. No.: 18/983,824

(22) Filed: Dec. 17, 2024

(30) Foreign Application Priority Data
Dec. 18, 2023 (CN) 202323462091.4

(51) Int. Cl. H01R 12/79; H01R 13/04; H01R 13/502; H01R 13/627

(52) U.S. Cl. CPC H01R 12/79; H01R 13/04; H01R 13/502; H01R 13/6272

(57) ABSTRACT

High-voltage anti-condensation interconnection systems and connectors and circuit boards thereof. A system can include plug and receptacle connectors A plug connector includes a flexible cable with contact fingers separated by housing dividers. A receptacle connector includes housing engaging portions at a front end. The receptacle connector includes terminals having mating ends connected to respective engaging portions at the front end. When the connectors are mated, the terminals contact respective contact fingers. Each mating contact point is separated by features such as the divider and engaging portions. The receptacle housing includes separators extending from a rear end and beyond a bottom face. Tails of the terminals are configured to contact respective contact pads of a circuit board. The separators are configured to have distal ends extending into openings of the circuit board. Each mounting contact point is separated by features such as the openings and the separators.

### CROSS-REFERENCE TO RELATED APPLICATIONS

This application claims priority to and the benefit of Chinese Patent Application Serial No. 202323462091.4, filed on Dec. 18, 2023, the contents of which are incorporated herein by reference in their entirety.

### TECHNICAL FIELD

This application relates generally to interconnection systems, such as those including electrical connectors, used to interconnect electronic assemblies.

### BACKGROUND

Electrical connectors are used in many electronic systems. It is generally easier and more cost effective to manufacture a system as separate electronic assemblies, which may be joined with electrical connectors. Electrical connectors may be used for interconnecting electronic assemblies so that the electronic assemblies may operate together as part of a system. Connectors, for example, may be mounted on printed circuit boards within two assemblies that are connected by mating the connectors. In other systems, it may be impractical to join two printed circuit boards by directly mating connectors on those printed circuit boards. For example, when the system is assembled, those printed circuit boards may be separated by too great a distance for a direct connection between connectors mounted to the printed circuit boards.

In some systems, connections between electronic assemblies may be made through cables. The cables may be terminated with connectors that mate with connectors mounted on a printed circuit board. In this way, connections between electronic assemblies may be made by plugging a connector that is part of a cable assembly into a board connector that is mounted to the printed circuit board. In other system architectures, a connector terminating a cable may be mated with another connector terminating another cable.

An example of a system in which assemblies are connected through cables is a modern automobile. For example, automotive vehicles include electronic control units (ECUs) for controlling various vehicle systems, such as the engine control unit, transmission control unit (TCUs), battery management system (BMS), cell sensing circuit (CSC), security systems, emissions control system, lighting control units, advanced driver assistance systems (ADAS), entertainment systems, navigation systems, and cameras. These electronic control units may be manufactured as separate assemblies. To simplify manufacture of an automobile, the assemblies may be connected via cables that are terminated with connectors that enable connections to mating board connectors terminating other cables or attached to printed circuit boards within the assemblies.

An automobile presents a harsh environment for an electrical connector. The automobile may vibrate, which can cause a connector to unmate and cease working entirely. Even if the vibration does not completely prevent operation of the connector, it can cause electrical noise, which can interfere with operation of electronics joined through interconnects including connectors. Noise, for example, may result from relative movement of components within connectors, which can change the electrical properties of the connector. Variations in the electrical properties, in turn, cause variation in the signals passing through the interconnect, which is a form of noise that interferes with processing the underlying signal.

In an automotive environment, electrical noise might also arise from automotive components that generate electromagnetic radiation. That radiation can couple to the conductive structures of a connector, creating noise on any signals passing over those conductive structures. In an automobile, any of a number of components might generate electromagnetic radiation, such as spark plugs, alternators or power switches. Noise can be particularly disruptive for high speed signals such as those use to communicate data over an automobile network.

### BRIEF SUMMARY

Aspects of the present disclosure relate to high-voltage anti-condensation interconnection systems and connectors and circuit boards thereof.

Some embodiments relate to a plug connector. The plug connector may comprise a housing comprising a front end, a rear end opposite the front end, and a plurality of dividers separating the front end into a plurality of mating portions; and a flexible cable comprising a plurality of contact fingers each disposed in a respective one of the plurality of mating portions of the housing, and a plurality of gaps separating adjacent contact fingers of the plurality of contact fingers, wherein each of the plurality of gaps of the flexible cable receives a respective one of the plurality of dividers of the housing so as to increase creepage distances between adjacent contact fingers of the plurality of contact fingers of the flexible cable.

Optionally, the plurality of contact fingers of the flexible cable extend in a rearward direction by a first distance; and the plurality of dividers of the housing extend in the rearward direction by a second distance greater than the first distance.

Optionally, the housing comprises a bottom face; and the front end of the housing comprises a plurality of ribs extending beyond the bottom face so as to increase creepage distances between adjacent contact fingers of the plurality of contact fingers of the flexible cable in a vertical direction.

Optionally, each of the plurality of ribs extends from a respective one of the plurality of dividers so as to increase creepage distances between adjacent contact fingers of the plurality of contact fingers of the flexible cable at the front end of the housing.

Optionally, the rear end of the housing comprises a plurality of guiding portions each connected to a respective one of the plurality of dividers so as to increase creepage distances between adjacent contact fingers of the plurality of contact fingers of the flexible cable at the rear end of the housing.

Optionally, the flexible cable comprise a flexible flat cable (FFC), and/or a flexible circuit board (FPC).

Optionally, the plug connector may further comprise a latching member configured to fix the plurality of contact fingers of the flexible cable in the housing.

Some embodiments relate to a receptacle connector. The receptacle connector may comprise a housing comprising a front end and a rear end opposite the front end, the front end comprising a recess enclosed by a flange and a plurality of engaging portions; and a plurality of terminals, each of the plurality of terminals comprising a mating end connected to a respective one of the plurality of engaging portions at the front end of the housing, and a tail extending out of the rear end of the housing.

Optionally, the flange comprises a plurality of grooves disposed between adjacent ones of the plurality of engaging portions so as to increase vertical creepage distances between adjacent mating ends of the plurality of terminals.

Optionally, the housing comprises a plurality of separators extending from the rear end and beyond a bottom face of the housing; and the tails of the plurality of terminals are disposed between respective adjacent separators of the plurality of separators of the housing.

Some embodiments relate to an electronic system. The electronic system may comprise the receptacle connector described herein; and a circuit board comprising a plurality of contact pads each configured to contact a tail of the plurality of terminals of the receptacle connector, and a plurality of openings each configured to receive a distal end of a respective separator of the plurality of separators of the housing of the receptacle connector so as to increase creepage distances between adjacent contact pads of the plurality of contact pads.

Optionally, the plurality of openings of the circuit board extend farther from the rear end of the housing than the plurality of separators.

Optionally, the electronic system further comprise a plug connector comprising a housing comprising a plurality of mating portions separated by a plurality of dividers, each of the plurality of mating portions configured to receive an engaging portion of the plurality of engaging portions of the receptacle connector; and a flexible cable comprising a plurality of contact fingers each disposed in a respective one of the plurality of mating portions of the housing, each of the plurality of contact fingers configured to contact a mating end of a respective terminal of the plurality of terminals of the receptacle connector.

Optionally, the housing of the plug connector comprises a plurality of ribs each extending from a respective one of the plurality of dividers and having an end disposed in a respective groove of the plurality of grooves of the flange of the receptacle connector.

Optionally, the plurality of dividers extend from a front end of the housing to a rear end of the housing.

Optionally, the electronic system further comprises a connector position assurance device configured to secure the housing of the plug connector to the housing of the receptacle connector.

Some embodiments relate to a circuit board. The circuit board may comprise a contact region for receiving tails of an electrical connector, the contact region comprising a plurality of contact pads aligned in a row direction; and a plurality of elongated openings aligned in the row direction, wherein the plurality of contact pads and the plurality of elongated openings are disposed in alternative so as to increase creepage distances between adjacent contact pads of the plurality of contact pads.

Optionally, each of the plurality of contact pads has a first length in a direction perpendicular to the row direction; each of the plurality of elongated openings has a second length in the direction perpendicular to the row direction; and the second length is greater than the first length.

Some embodiments relate to an electronic system. The electronic system may comprise the circuit board described herein; and a receptacle connector comprising: a housing comprising a plurality of separators extending from a rear end of the housing, each of the plurality of separators extending into a respective opening of the plurality of elongated openings; and a plurality of terminals, each of the plurality of terminals comprising a tail extending out of the rear end of the housing and configured to contact a respective one of the plurality of contact pads.

Optionally, the plurality of separators of the receptacle connector extend farther from the rear end of the housing than the tails of the plurality of terminals of the receptacle connector; and the plurality of elongated openings of the circuit board extend farther from the rear end of the housing than the plurality of separators of the receptacle connector.

Some embodiments relate to an electronic system. The electronic system may comprise a plug connector and a receptacle connector. The plug connector may include a flexible cable, and a receptacle connector for connection to a circuit board. One end of the plug connector may be a first front end. The flexible cable may be provided with contact fingers near the first front end. The first front end may be provided with first mating portions. A divider may be provided between adjacent said first mating portions. Adjacent said contact fingers may be separated by the divider and respectively disposed at different said first mating portions. The receptacle connector may comprise a housing and terminals extending along two ends of the housing. One end of the housing may be a second front end. The second front end may be provided with engaging portions. The engaging portion may be inserted into the first mating portion and formed with a cavity. The terminal and the contact finger may be connected in the cavity. Another end of the receptacle connector may be a second rear end for connection to a circuit board. The second rear end may be provided with separators. The terminals may be arranged alternately with the separators at the second rear end.

Optionally, a length of the divider may be greater than or equal to a length of the contact finger.

Optionally, a rib may be further provided between adjacent said first mating portions, a groove adapted to the rib may be provided between adjacent said engaging portions, and the rib may be limited in the groove.

Optionally, the plug connector may be further provided with a bottom face connected to the first front end. The rib may extend from the first front end to the bottom face.

Optionally, the housing may be provided with a recess. The engaging portions may be disposed in the recess.

Optionally, an end of the plug connector opposite the first front end may be a first rear end. The plug connector may be provided with a guiding portion extending from the first rear end toward the first front end. The flexible cable may be provided with a gap adapted to the guiding portion.

Optionally, the gap may be disposed between adjacent said contact fingers. The guiding portion may be formed integrally with the divider.

Optionally, the connector may further comprise a contact region. The contact region may be further provided with openings. The openings may be disposed between adjacent said terminals.

Optionally, the separators may be limited in the openings.

Optionally, the connector may further comprise a connector position assurance device and a latching member disposed on the plug connector. The plug connector may be fixedly connected to the receptacle connector by means of the latching member and the connector position assurance device.

These techniques may be used alone or in any suitable combination. The foregoing summaries are provided by way of illustration and are not intended to be limiting.

### BRIEF DESCRIPTION OF THE DRAWINGS

The accompanying drawings are not intended to be drawn to scale. In the drawings, identical or nearly identical components that are illustrated in various figures may be represented by a like numeral. For purposes of clarity, not every component may be labeled in every drawing. In the drawings:

FIG. 1 is an exploded perspective view of an electronic system comprising a plug connector and a receptacle connector, according to some embodiments.

FIG. 2 is a perspective view of the electronic system of FIG. 1, showing the receptacle connector mounted to a circuit board, according to some embodiments.

FIG. 3 is a front, bottom perspective view of a plug connector of the electronic system of FIG. 1, showing a front end, according to some embodiments.

FIG. 4 is a top, rear perspective view of the plug connector of FIG. 3, according to some embodiments.

FIG. 5 is a front perspective view of a receptacle connector of the electronic system of FIG. 1, according to some embodiments.

FIG. 6 is a rear perspective view of the receptacle connector of FIG. 5, according to some embodiments.

FIG. 7 is a perspective view of a portion of the electronic system of FIG. 1, showing the receptacle connector of FIG. 5 mounted to a circuit board, according to some embodiments.

FIG. 8 is a cross-sectional perspective view of the electronic system of FIG. 1 along a line marked “A-A” in FIG. 2, according to some embodiments.

FIG. 9 is a cross-sectional perspective view of the electronic system of FIG. 1 along a line marked “B-B” in FIG. 8, according to some embodiments.

FIG. 10 is a cross-sectional view of the electronic system of FIG. 1 along a surface of the circuit board, according to some embodiments.

### DETAILED DESCRIPTION

The inventors have recognized and appreciated techniques for making high-voltage anti-condensation interconnection systems for use in a harsh environment such as one presented by an automobile. Conventional connectors may be susceptible to breakdowns at certain voltages required by current systems, causing system failures. Further, current systems may produce increased heat during operating, creating a temperature differential between the system and its operating environment. This temperature difference can result in condensation forming within the system, which may accumulate, create unintended electrical connections, and further contribute to system failures.

According to aspects of the present disclosure, a system may include circuit boards and/or flexible cables interconnected via electrical connectors. In some embodiments, a system may include a plug connector comprising a flexible cable, and a receptacle connector configured to mate with the plug connector at a mating end and mount to a circuit board at a mounting end so as to connect the circuit board and the flexible cable. The flexible cables may include flexible flat cables (FFC), and/or a flexible circuit boards (FPC).

In some embodiments, the plug connector may include a housing having a front end, and a rear end, and a plurality of dividers separating the front end into a plurality of mating portions. A flexible cable may have a plurality of contact fingers separated by gaps. The flexible cable may have an end inserted in the housing, with the gaps receiving the dividers of the housing, so that the contact fingers are separated by the dividers of the housing.

Such a configuration may increase creepage distances and clearance distances between adjacent contact fingers at the front end, enabling the connector to meet high-voltage requirements. Creepage distance may refer to the path length along surfaces between two conductors across which the high voltage may exist in operation. Clearance may refer to a shortest path through air between two conductors across which the high voltage may exist in operation. The creepage and clearance distance that precludes arcing may depend on factors, such as the magnitude of the voltage across adjacent conductors in the connector and the degree of contamination in the operating environment. In some embodiments, the housing of the plug connector may include guiding portions each connected to a respective divider so as to increase creepage distances between adjacent contact fingers at the rear end of the housing. Such a configuration may also reduce the risk of the creation of unintended electrical connections by condensation.

In some embodiments, the front end of the housing of the plug connector may include a plurality of ribs each extending from a respective divider. In some embodiments, the ribs may extend beyond a bottom face of the housing. The ribs may further increase creepage distances and clearance distances between adjacent contact fingers at the front end in both a lateral direction perpendicular to a mating direction of the connector and a vertical direction perpendicular to both the mating direction and the lateral direction.

In some embodiments, a receptacle connector may include a housing and a plurality of terminals held by the housing. The housing may have a front end, a rear end, and a plurality of separators extending from the rear end and beyond a bottom face of the housing. The front end may have a plurality of engaging portions configured to be inserted into the mating portions of the plug connector. Each terminal may include a mating end connected to a respective engaging portion, and a tail extending out of the rear end of the housing and disposed between adjacent separators. Such a configuration may increase creepage distances and clearance distances between adjacent terminals at both the mating ends and the tails, enabling the connector to meet high-voltage requirements.

In some embodiments, the front end of the housing of the receptacle connector may include a recess enclosed by a flange. The plurality of engaging portions may be disposed in the recess. The recess may be configured to receive the mating portions of the plug connector, with the flange substantially enclosing the mating portions of the plug connector. In some embodiments, the flange may comprise a plurality of grooves disposed between adjacent engaging portions and configured to receive respective ribs of the housing of the plug connector. further increase creepage distances and clearance distances between adjacent terminals.

In some embodiments, when the connectors are mated, the mating ends of the terminals of the receptacle connector contact respective contact fingers of the flexible cable of the plug connector. Each mating contact point may be separated from each other by features such as the divider and engaging portions.

In some embodiments, a circuit board may include a plurality of contact pads aligned in a row, and a plurality of elongated openings aligned in the same row and disposed between adjacent contact pads. The openings may extend longer than the contact pads in a direction perpendicular to the row. Such a configuration may increase creepage distances and clearance distances between adjacent contact pads.

In some embodiments, tails of the terminals of the receptacle connector may be configured to contact respective contact pads. The separators of the housing of the receptacle connector may be configured to extend into the openings of the circuit board. Each mounting contact point may be separated by features such as the openings and the separators. Such a configuration may increase creepage distances and clearance distances between adjacent contact pads of the circuit board and between adjacent tails of the terminals of the receptacle connector.

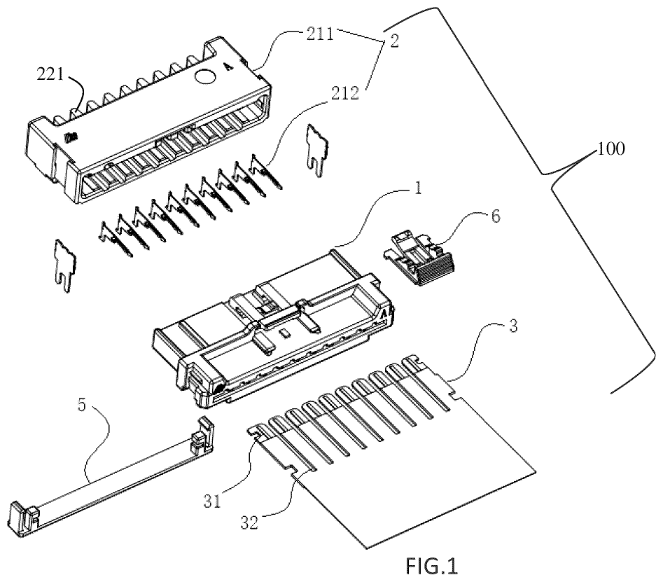

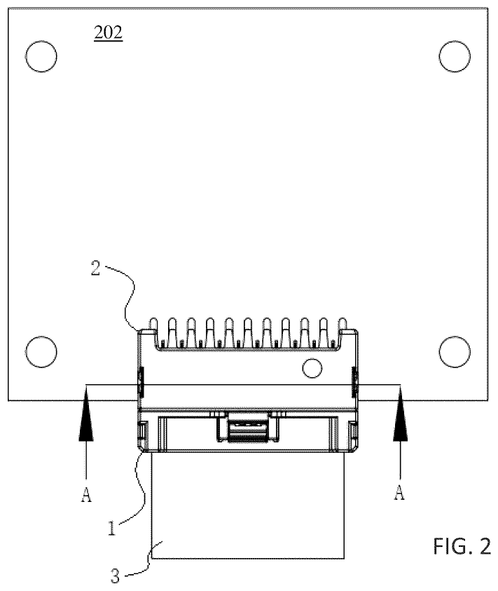

FIG. 1 is an exploded perspective view of an electronic system 100 comprising a plug connector 1 and a receptacle connector 2. FIG. 2 is a perspective view of the electronic system 100, with the receptacle connector 2 mounted to a circuit board 202. The plug connector 1 and the receptacle connector 2 may be connected to each other by insertion, and establish connections between a flexible cable 3 to the circuit board 202. The flexible cable 3 may include a flexible flat cable (FFC), and/or a flexible circuit board (FPC).

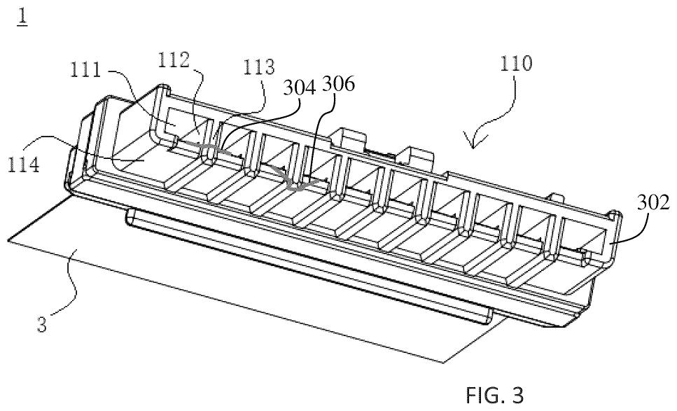

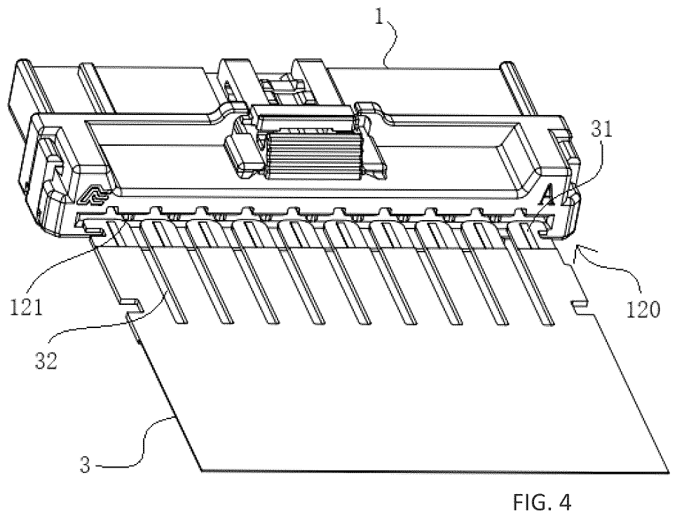

FIG. 3 is a front, bottom perspective view of the plug connector 1. FIG. 4 is a top, rear perspective view of the plug connector 1. As illustrated, the plug connector 1 may include the flexible cable 3. The flexible cable 3 may comprise contact fingers 31 at one end. The housing 302 of the plug connector 1 may include a first front end 110 for connecting to the receptacle connector 2. The contact fingers 31 of the flexible cable 3 may be disposed at the first front end 110. First mating portions 111 may be provided at the first front end 110, with a divider 112 between adjacent first mating portions 111. Different contact fingers 31 may be disposed at different first mating portions 111, with adjacent contact fingers 31 being separated by the divider 112. In some embodiments, the dividers 112 may extend closer to a first rear end 120 of the housing 302 than the contact fingers 31 of the flexible cable. In this way, at the first front end 110, both the lateral creepage distance (e.g., illustrative line 304) and the vertical creepage distance (e.g., illustrative line 306) between adjacent contact fingers 31 can be increased, enabling the connector to meet high-voltage application requirements.

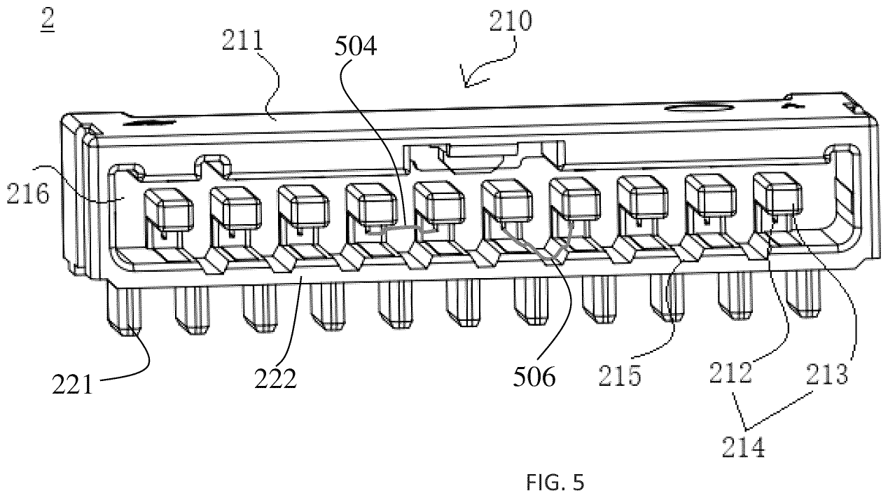

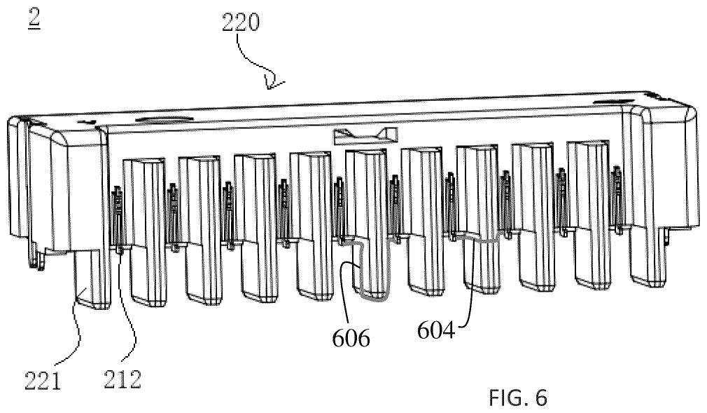

FIG. 5 is a front perspective view of the receptacle connector 2. FIG. 6 is a rear perspective view of the receptacle connector 2. The receptacle connector 2 may be configured for connection to a contact region 4 of the circuit board 202. The receptacle connector 2 may comprise a housing 211 and terminals 212 extending between two ends of the housing 211. The receptacle connector 2 may comprise a second front end 210 configured for connection to the first front end 110 of the plug connector 1. The second front end 210 may comprise engaging portions 213. Each terminal 212 may comprise a mating end, connected to the engaging portion 213 and configured for connection to the contact finger 31 on the flexible cable 3. At the second front end 210, the terminal 212 and the engaging portion 213 form a second mating portion 214. The engaging portion 213 may include a protrusion from the housing 211 toward the second front end 210. As illustrated, the mating end of the terminal 212 may be disposed below the engaging portion 213. A space facilitating connection to the contact finger 31 of the flexible cable 3 by insertion may be formed below the engaging portion 213. The second mating portion 214 may be adapted to the first mating portion 111.

The housing 211 may include a second rear end 220. Each terminal 212 may include at the second rear end 220 a tail such as a soldering pin configured for connecting to the contact region/circuit board. The housing 211 may include separators 221 at the second rear end 220.

The separators 221 may be arranged alternately with the terminals 212. As illustrated, the separators 221 may extend farther from the second rear end 220 than the tails of the terminals 212. In this way, at the second front end 210, both the lateral creepage distance (e.g., illustrative line 504) and the vertical creepage distance (e.g., illustrative line 506) between adjacent terminals 212 can be increased, enabling the connector to meet high-voltage application requirements.

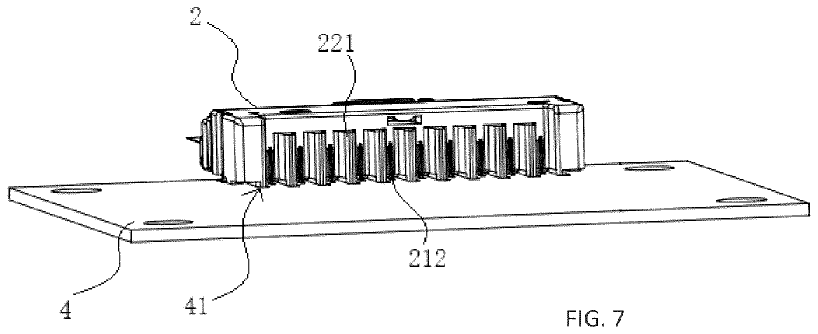

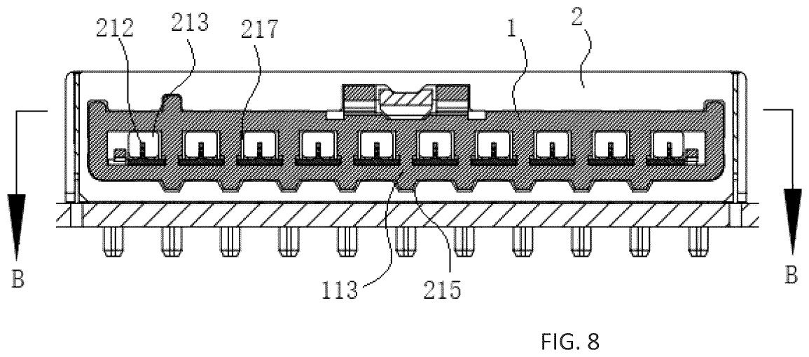

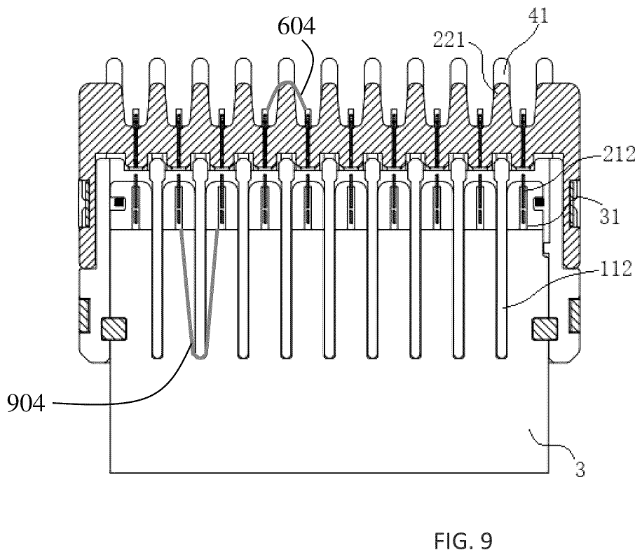

FIG. 7 is a perspective view of a portion of the electronic system 100, showing the receptacle connector 2 mounted to the circuit board 202. FIG. 8 is a cross-sectional perspective view of the electronic system 100 along a line marked “A-A” in FIG. 2. FIG. 9 is a cross-sectional perspective view of the electronic system 100 along a line marked “B-B” in FIG. 8.

Referring to FIGS. 2, 7, 8 and 9, the plug connector 1 may be moved toward the receptacle connector 2 for inserting the engaging portions 213 into the first mating portions 111 and connecting the terminals 212 of the receptacle connector 2 to the contact fingers 31 of the plug connector 1. When mating is complete, a cavity 217 may be formed between the engaging portion 213 and the divider 112. A contact point formed by connection of the terminal 212 to the contact finger 31 may be disposed in the cavity 217. The contact points may be independent of each other, separated by the engaging portions 213 and the dividers 112. When condensation occurs in the connectors, the condensation is prevented from bridging adjacent contact points by the engaging portions 213 and the dividers 112. Such a configuration reduces the risk of short circuits or leakage current, etc. due to condensation, increasing the service life and safety of the connector. At the second rear end 220 of the receptacle connector 2, the separators 221 may increase both the lateral creepage distance (e.g., illustrative line 604) and the vertical creepage distance (e.g., illustrative line 606) between adjacent terminals 212, enabling the connector to meet high-voltage application requirements.

The electronic system 100 may further comprise a latching member 5 and a connector position assurance device 6. The latching member 5 and the connector position assurance device 6 may be provided on the plug connector 1. The plug connector 1 may be further fixedly connected to the receptacle connector 2 by the connector position assurance device 6, securing the plug connector 1 to the receptacle connector 2. The flexible cable may be fixedly connected to the housing 302 of the plug connector 1 by the latching member 5.

In some embodiments, referring to FIG. 9, to further improve the performance of the connector, the length of the divider 112 may be greater than or equal to the length of the contact finger 31, thus further increasing the path distance between adjacent contact fingers 31, and improving anti-condensation functionality.

In some embodiments, referring to FIGS. 3, 5 and 8, the plug connector 1 may comprise ribs 113 between adjacent first mating portions 111, and the receptacle connector 2 may comprise grooves 215 adapted to the ribs 113 between adjacent second mating portions 214. When the receptacle connector 2 and the plug connector 1 are connected by engagement, the ribs 113 may be limited in the grooves 215, increasing the creepage distance between adjacent terminals 212. The plug connector 1 may be further provided with a bottom face 114 connected to the first front end 110. As illustrated, the rib 113 may extend from the first front end 110 to the bottom face 114 of the plug connector 1, and the rib 113 may be integrally formed with the divider 112. Alternatively, in some embodiments, the rib 113 may not extend to the bottom face 114 of the plug connector 1, or the rib 113 may be separate from the divider 112.

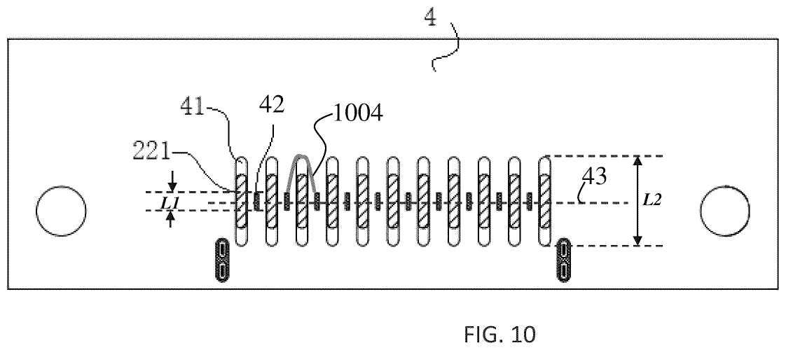

FIG. 10 is a cross-sectional view of the electronic system 100 along a surface of the circuit board 202. Referring to FIGS. 6, 7, 9 and 10, the circuit board 202 may comprise a contact region 4 having a plurality of contact pads 42 configured for receiving tails of the terminals 212 of the receptacle connector 2. For example, the receptacle connector 2 may be connected to the contact region 4 via the soldering pins of the terminals 212. The contact pads 42 may be aligned in a row direction 43. Each contact pad 42 may have a first length L1 in a direction perpendicular to the row direction 43. Openings 41 may be provided in the contact region 4. The openings 41 may be aligned in the row direction 43 and arranged alternately with the contact pads 42. Each opening 41 may have a second length L2 in the direction perpendicular to the row direction 43 and greater than the first length L1 of the contact pad 42. As illustrated, the separators 221 may extend into the openings 41. The openings 41 may extend farther from the second rear end 220 of the housing 211 of the receptacle connector 2 than the separators 221 of the receptacle connector 2. The openings 41 can increase the creepage distance between adjacent contact pads 42 (e.g., illustrative line 904) at the contact region 4. In some embodiments, the opening 41 may have a greater length than the separator 221. Such a configuration can increase the creepage distance between contact pads 42, and improve the performance of the electronic system 100.

In some embodiments, the housing 211 may comprise a recess 216 adapted to the first front end 110 of the plug connector 1. The housing 211 may comprise a flange 222 enclosing the recess 216. The flange 222 may comprise the grooves 215. Second mating portions 214 may be disposed in the recess 216. When the receptacle connector 2 and the plug connector 1 are connected, the recess 216 may perform an aligning and guiding action, and make the connection between the receptacle connector 2 and the plug connector 1 more stable.

In some embodiments, a guiding structure may be provided between the first rear end 120 and the flexible cable 3. The plug connector 1 may be provided with guiding portions 121 extending from the first rear end 120 toward the first front end 110. The flexible cable 3 may be provided with gaps 32 adapted to the guiding portions 121. During installation, the gaps 32 may be inserted into the plug connector 1 along the guiding portions 121, such that the contact fingers 31 are separated at different first mating portions 111. As illustrated, the gaps 32 may be disposed between adjacent contact fingers 31, and the guiding portions 121 may be integrally connected to the dividers 112, such that the contact fingers 31 are separated in the process of fitting the flexible cable 3 to the plug connector 1. In some embodiments, the guiding portions 121 may be provided separately from the dividers 112. In this way, at the first rear end 120, the creepage distance (e.g., illustrative line 904) between adjacent contact fingers 31 can be increased, enabling the connector to meet high-voltage application requirements.

Various aspects are described in this disclosure, which include, but are not limited to, the following aspects:
1. An electronic system, comprising a plug connector (e.g., 1), a flexible cable (e.g., 3) connected to the plug connector (e.g., 1), and a receptacle connector (e.g., 2) for connection to a circuit board; the plug connector (e.g., 1) comprising a first front end (e.g., 110), the flexible cable (e.g., 3) provided with contact fingers (e.g., 31) near the first front end (e.g., 110), the first front end (e.g., 110) provided with first mating portions (e.g., 111), a divider (e.g., 112) provided between adjacent said first mating portions (e.g., 111), adjacent said contact fingers (e.g., 31) separated by the divider (e.g., 112) and respectively disposed at different said first mating portions (e.g., 111); the receptacle connector (e.g., 2) comprises a housing (e.g., 211) and terminals (e.g., 212) extending along two ends of the housing (e.g., 211), the housing (e.g., 211) comprising a second front end (e.g., 210), the second front end (e.g., 210) provided with engaging portions (e.g., 213), the engaging portion (e.g., 213) inserted into the first mating portion (e.g., 111) and formed with a cavity (e.g., 217), the terminal (e.g., 212) and the contact finger (e.g., 31) connected in the cavity (e.g., 217); another end of the receptacle connector (e.g., 2) a second rear end (e.g., 220) for connection to a circuit board, the second rear end (e.g., 220) provided with separators (e.g., 221), and the terminals (e.g., 212) arranged alternately with the separators (e.g., 221) at the second rear end (e.g., 220).
2. The electronic system of aspect 1, wherein a length of the divider (e.g., 112) is greater than or equal to a length of the contact finger (e.g., 31).
3. The electronic system of aspect 1, wherein a rib (e.g., 113) is further provided between adjacent said first mating portions (e.g., 111), a groove (e.g., 215) adapted to the rib (e.g., 113) is provided between adjacent said engaging portions (e.g., 213), and the rib (e.g., 113) is limited in the groove (e.g., 215).
4. The electronic system of aspect 3, wherein the plug connector (e.g., 1) is further provided with a bottom face (e.g., 114) connected to the first front end (e.g., 110), and the rib (e.g., 113) extends from the first front end (e.g., 110) to the bottom face (e.g., 114).
5. The electronic system of aspect 1, wherein the housing (e.g., 211) is provided with a recess (e.g., 216), the engaging portions (e.g., 213) disposed in the recess (e.g., 216).
6. The electronic system of aspect 1, wherein an end of the plug connector (e.g., 1) opposite the first front end (e.g., 110) is an first rear end (e.g., 120), the plug connector (e.g., 1) is provided with a guiding portion (e.g., 121) extending from the first rear end (e.g., 120) toward the first front end (e.g., 110), and the flexible cable (e.g., 3) is provided with a gap (e.g., 32) adapted to the guiding portion (e.g., 121).
7. The electronic system of aspect 6, wherein the gap (e.g., 32) is disposed between adjacent said contact fingers (e.g., 31), and the guiding portion (e.g., 121) is formed integrally with the divider (e.g., 112).
8. The electronic system of aspect 5, further comprising a contact region (e.g., 4), the contact region (e.g., 4) further provided with openings (e.g., 41), the openings (e.g., 41) disposed between adjacent said terminals (e.g., 212).
9. The electronic system of aspect 8, wherein the separators (e.g., 221) are limited in the openings (e.g., 41).
10. The electronic system of aspect 1, further comprising a connector position assurance device (e.g., 6) and a latching member (e.g., 5) disposed on the plug connector (e.g., 1), the plug connector (e.g., 1) fixedly connected to the receptacle connector (e.g., 2) by means of the latching member (e.g., 5) and the connector position assurance device (e.g., 6).
11. A plug connector (e.g., 1) comprising a housing comprising a front end (e.g., 110), a rear end (e.g., 120) opposite the front end, and a plurality of dividers (e.g., 112) separating the front end into a plurality of mating portions (e.g., 111); and a flexible cable (e.g., 3) comprising a plurality of contact fingers (e.g., 31) each disposed in a respective one of the plurality of mating portions of the housing, and a plurality of gaps (e.g., 32) separating adjacent contact fingers of the plurality of contact fingers, wherein each of the plurality of gaps of the flexible cable receives a respective one of the plurality of dividers of the housing so as to increase creepage distances between adjacent contact fingers of the plurality of contact fingers of the flexible cable.
12. The plug connector of aspect 11, wherein the plurality of contact fingers of the flexible cable extend in a rearward direction by a first distance; and the plurality of dividers of the housing extend in the rearward direction by a second distance greater than the first distance.
13. The plug connector of aspect 12, wherein the housing comprises a bottom face (e.g., 114); and the front end of the housing comprises a plurality of ribs (e.g., 113) extending beyond the bottom face so as to increase creepage distances between adjacent contact fingers of the plurality of contact fingers of the flexible cable in a vertical direction.
14. The plug connector of aspect 13, wherein each of the plurality of ribs extends from a respective one of the plurality of dividers so as to increase creepage distances between adjacent contact fingers of the plurality of contact fingers of the flexible cable at the front end of the housing.
15. The plug connector of aspect 14, wherein the rear end of the housing comprises a plurality of guiding portions (e.g., 121) each connected to a respective one of the plurality of dividers so as to increase creepage distances between adjacent contact fingers of the plurality of contact fingers of the flexible cable at the rear end of the housing.
16. The plug connector of aspect 15, wherein the flexible cable comprise a flexible flat cable (FFC), and/or a flexible circuit board (FPC).
17. The plug connector of aspect 16, further comprising a latching member (e.g., 5) configured to fix the plurality of contact fingers of the flexible cable in the housing.
18. A receptacle connector (e.g., 2) comprising a housing comprising a front end (e.g., 210) and a rear end (e.g., 220) opposite the front end, the front end comprising a recess (e.g., 216) enclosed by a flange (e.g., 222) and a plurality of engaging portions (e.g., 213); and a plurality of terminals (e.g., 212), each of the plurality of terminals comprising a mating end connected to a respective one of the plurality of engaging portions at the front end of the housing, and a tail extending out of the rear end of the housing.
19. The receptacle connector of aspect 18, wherein the flange comprises a plurality of grooves (e.g., 215) disposed between adjacent ones of the plurality of engaging portions so as to increase vertical creepage distances between adjacent mating ends of the plurality of terminals.
20. The receptacle connector of aspect 19, wherein the housing comprises a plurality of separators (e.g., 221) extending from the rear end and beyond a bottom face of the housing; and the tails of the plurality of terminals are disposed between respective adjacent separators of the plurality of separators of the housing.
21. An electronic system comprising the receptacle connector of aspect 20; and a circuit board (e.g., 4) comprising a plurality of contact pads (e.g., 42) each configured to contact a tail of the plurality of terminals of the receptacle connector, and a plurality of openings (e.g., 41) each configured to receive a distal end of a respective separator of the plurality of separators of the housing of the receptacle connector so as to increase creepage distances between adjacent contact pads of the plurality of contact pads.
22. The electronic system of aspect 21, wherein the plurality of openings of the circuit board extend farther from the rear end of the housing than the plurality of separators.
23. The electronic system of aspect 21, further comprising a plug connector comprising a housing comprising a plurality of mating portions separated by a plurality of dividers, each of the plurality of mating portions configured to receive an engaging portion of the plurality of engaging portions of the receptacle connector; and a flexible cable comprising a plurality of contact fingers each disposed in a respective one of the plurality of mating portions of the housing, each of the plurality of contact fingers configured to contact a mating end of a respective terminal of the plurality of terminals of the receptacle connector.
24. The electronic system of aspect 23, wherein the housing of the plug connector comprises a plurality of ribs each extending from a respective one of the plurality of dividers and having an end disposed in a respective groove of the plurality of grooves of the flange of the receptacle connector.
25. The electronic system of aspect 24, wherein the plurality of dividers extend from a front end of the housing to a rear end of the housing.
26. The electronic system of aspect 23, further comprising a connector position assurance device configured to secure the housing of the plug connector to the housing of the receptacle connector.
27. A circuit board (e.g., 4) comprising a contact region for receiving tails of an electrical connector, the contact region comprising a plurality of contact pads (e.g., 42) aligned in a row direction; and a plurality of elongated openings (e.g., 41) aligned in the row direction, wherein the plurality of contact pads and the plurality of elongated openings are disposed in alternative so as to increase creepage distances between adjacent contact pads of the plurality of contact pads.
28. The circuit board of aspect 27, wherein each of the plurality of contact pads has a first length (e.g., L1) in a direction perpendicular to the row direction; each of the plurality of elongated openings has a second length (e.g., L2) in the direction perpendicular to the row direction; and the second length is greater than the first length.
29. An electronic system comprising the circuit board of aspect 27; and a receptacle connector comprising: a housing comprising a plurality of separators extending from a rear end of the housing, each of the plurality of separators extending into a respective opening of the plurality of elongated openings; and a plurality of terminals, each of the plurality of terminals comprising a tail extending out of the rear end of the housing and configured to contact a respective one of the plurality of contact pads.
30. The electronic system of aspect 29, wherein the plurality of separators of the receptacle connector extend farther from the rear end of the housing than the tails of the plurality of terminals of the receptacle connector; and the plurality of elongated openings of the circuit board extend farther from the rear end of the housing than the plurality of separators of the receptacle connector.

Having thus described several aspects of several embodiments, it is to be appreciated that various alterations, modifications, and improvements will readily occur to those skilled in the art. Such alterations, modifications, and improvements are intended to be part of this disclosure and are intended to be within the spirit and scope of the invention. While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

As an example, although many creative aspects have been described above with reference to right angle connectors, it should be understood that the aspects of the present disclosure are not limited to these. Any one of the creative features, whether alone or combined with one or more other creative features, can also be used for other types of electrical connectors, such as vertical connectors, etc.

Further, though some advantages of the present invention may be indicated, it should be appreciated that not every embodiment of the invention will include every described advantage. Some embodiments may not implement any features described as advantageous. Accordingly, the foregoing description and drawings are by way of example only.

Also, the technology described may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used, should be understood to control over dictionary definitions, definitions in documents incorporated by reference, and/or ordinary meanings of the defined terms.

In the description of the present disclosure, it is to be understood that orientation or positional relationships indicated by orientation words “front”, “rear,” “upper,” “lower,” “left,” “right,” “transverse direction,” “vertical direction,” “perpendicular,” “horizontal,” “top,” “bottom” and the like are shown based on the accompanying drawings, for the purposes of the ease in describing the present disclosure and simplification of its descriptions. Unless stated to the contrary, these orientation words do not indicate or imply that the specified apparatus or element has to be specifically located, and structured and operated in a specific direction, and therefore, should not be understood as limitations to the present disclosure. The orientation words “inside” and “outside” refer to the inside and outside relative to the contour of each component itself.

For facilitating description, the spatial relative terms such as “on,” “above,” “on an upper surface of” and “upper” may be used here to describe a spatial position relationship between one or more components or features and other components or features shown in the accompanying drawings. It should be understood that the spatial relative terms not only include the orientations of the components shown in the accompanying drawings, but also include different orientations in use or operation. For example, if the component in the accompanying drawings is turned upside down completely, the component “above other components or features” or “on other components or features” will include the case where the component is “below other components or features” or “under other components or features.” Thus, the exemplary term “above” can encompass both the orientations of “above” and “below.” In addition, these components or features may be otherwise oriented (for example rotated by 90 degrees or other angles) and the present disclosure is intended to include all these cases.

It should be noted that the terms used herein are for describing specific embodiments, and are not intended to limit the exemplary embodiments according to the present application. As used herein, an expression of a singular form includes an expression of a plural form unless otherwise indicated. In addition, it should also be understood that when the terms “including” and/or “comprising” are used herein, it indicates the presence of features, steps, operations, parts, components and/or combinations thereof.

Numerical values and ranges may be described in the specification and claims as approximate or exact values or ranges. For example, in some cases the terms “about,” “approximately,” and “substantially” may be used in reference to a value. Such references are intended to encompass the referenced value as well as plus and minus reasonable variations of the value. For example, a phrase “between about 10 and about 20” is intended to mean “between exactly 10 and exactly 20” in some embodiments, as well as “between 10±d1 and 20±d2” in some embodiments. The amount of variation d1, d2 for a value may be less than 5% of the value in some embodiments, less than 10% of the value in some embodiments, and yet less than 20% of the value in some embodiments. In embodiments where a large range of values is given, e.g., a range including two or more orders of magnitude, the amount of variation d1, d2 for a value could be as high as 50%. For example, if an operable range extends from 2 to 200, “approximately 80” may encompass values between 40 and 120 and the range may be as large as between 1 and 300. When only exact values are intended, the term “exactly” is used, e.g., “between exactly 2 and exactly 200.” The term “essentially” is used to indicate that values are the same or at a target value or condition to within ±3%.

The indefinite articles “a” and “an,” as used in the specification and in the claims, unless clearly indicated to the contrary, should be understood to mean “at least one.”

The phrase “and/or,” as used in the specification and in the claims, should be understood to mean “either or both” of the elements so conjoined, e.g., elements that are conjunctively present in some cases and disjunctively present in other cases. Multiple elements listed with “and/or” should be construed in the same fashion, e.g., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used in the specification and in the claims, “or” should be understood to have the same meaning as “and/or” as defined above. For example, when separating items in a list, “or” or “and/or” shall be interpreted as being inclusive, e.g., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also enables that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally Including other elements); etc.

In the claims, as well as in the specification above, all transitional phrases such as “comprising,” “including,” “carrying,” “having,” “containing,” “involving,” “holding,” “composed of,” and the like are to be understood to be open-ended, e.g., to mean including but not limited to. For example, a process, method, system, product or device that contains a series of steps or units need not be limited to those steps or units that are clearly listed, instead, it may include other steps or units that are not clearly listed or are inherent to these processes, methods, products or devices. Only the transitional phrases “consisting of” and “consisting essentially of” shall be closed or semi-closed transitional phrases, respectively.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

In the claims, as well as in the specification above, use of ordinal terms such as “first,” “second,” “third,” etc. does not by itself connote any priority, precedence, or order of one element over another or the temporal order in which acts of a method are performed, but are used merely as labels to distinguish one element having a certain name from another element having a same name (but for use of the ordinal term) to distinguish the elements.

1. A plug connector comprising:
a housing comprising a front end, a rear end opposite the front end, and a plurality of dividers separating the front end into a plurality of mating portions; and
a flexible cable comprising a plurality of contact fingers each disposed in a respective one of the plurality of mating portions of the housing, and a plurality of gaps separating adjacent contact fingers of the plurality of contact fingers, wherein:
each of the plurality of gaps of the flexible cable receives a respective one of the plurality of dividers of the housing so as to increase creepage distances between adjacent contact fingers of the plurality of contact fingers of the flexible cable.

2. The plug connector of claim 1, wherein:
the plurality of contact fingers of the flexible cable extend in a rearward direction by a first distance; and
the plurality of dividers of the housing extend in the rearward direction by a second distance greater than the first distance.

3. The plug connector of claim 2, wherein:
the housing comprises a bottom face; and
the front end of the housing comprises a plurality of ribs extending beyond the bottom face so as to increase creepage distances between adjacent contact fingers of the plurality of contact fingers of the flexible cable in a vertical direction.

4. The plug connector of claim 3, wherein:
each of the plurality of ribs extends from a respective one of the plurality of dividers so as to increase creepage distances between adjacent contact fingers of the plurality of contact fingers of the flexible cable at the front end of the housing.

5. The plug connector of claim 4, wherein:
the rear end of the housing comprises a plurality of guiding portions each connected to a respective one of the plurality of dividers so as to increase creepage distances between adjacent contact fingers of the plurality of contact fingers of the flexible cable at the rear end of the housing.

6. The plug connector of claim 5, wherein:
the flexible cable comprise a flexible flat cable (FFC), and/or a flexible circuit board (FPC).

7. The plug connector of claim 6, further comprising:
a latching member configured to fix the plurality of contact fingers of the flexible cable in the housing.

8. A receptacle connector comprising:
a housing comprising a front end and a rear end opposite the front end, the front end comprising a recess enclosed by a flange and a plurality of engaging portions; and
a plurality of terminals, each of the plurality of terminals comprising a mating end connected to a respective one of the plurality of engaging portions at the front end of the housing, and a tail extending out of the rear end of the housing.

9. The receptacle connector of claim 8, wherein:
the flange comprises a plurality of grooves disposed between adjacent ones of the plurality of engaging portions so as to increase vertical creepage distances between adjacent mating ends of the plurality of terminals.

10. The receptacle connector of claim 9, wherein:
the housing comprises a plurality of separators extending from the rear end and beyond a bottom face of the housing; and
the tails of the plurality of terminals are disposed between respective adjacent separators of the plurality of separators of the housing.

11. An electronic system comprising:
the receptacle connector of claim 10; and
a circuit board comprising:
a plurality of contact pads each configured to contact a tail of the plurality of terminals of the receptacle connector, and
a plurality of openings each configured to receive a distal end of a respective separator of the plurality of separators of the housing of the receptacle connector so as to increase creepage distances between adjacent contact pads of the plurality of contact pads.

12. The electronic system of claim 11, wherein:
the plurality of openings of the circuit board extend farther from the rear end of the housing than the plurality of separators.

13. The electronic system of claim 11, further comprising:
a plug connector comprising:
a housing comprising a plurality of mating portions separated by a plurality of dividers, each of the plurality of mating portions configured to receive an engaging portion of the plurality of engaging portions of the receptacle connector; and
a flexible cable comprising a plurality of contact fingers each disposed in a respective one of the plurality of mating portions of the housing, each of the plurality of contact fingers configured to contact a mating end of a respective terminal of the plurality of terminals of the receptacle connector.

14. The electronic system of claim 13, wherein:
the housing of the plug connector comprises a plurality of ribs each extending from a respective one of the plurality of dividers and having an end disposed in a respective groove of the plurality of grooves of the flange of the receptacle connector.

15. The electronic system of claim 14, wherein:
the plurality of dividers extend from a front end of the housing to a rear end of the housing.

16. The electronic system of claim 13, further comprising:
a connector position assurance device configured to secure the housing of the plug connector to the housing of the receptacle connector.

17. A circuit board comprising:
a contact region for receiving tails of an electrical connector, the contact region comprising:
a plurality of contact pads aligned in a row direction; and
a plurality of elongated openings aligned in the row direction,
wherein the plurality of contact pads and the plurality of elongated openings are disposed in alternative so as to increase creepage distances between adjacent contact pads of the plurality of contact pads.

18. The circuit board of claim 17, wherein:
each of the plurality of contact pads has a first length in a direction perpendicular to the row direction;
each of the plurality of elongated openings has a second length in the direction perpendicular to the row direction; and
the second length is greater than the first length.

19. An electronic system comprising:
the circuit board of claim 17; and
a receptacle connector comprising:
a housing comprising a plurality of separators extending from a rear end of the housing, each of the plurality of separators extending into a respective opening of the plurality of elongated openings; and
a plurality of terminals, each of the plurality of terminals comprising a tail extending out of the rear end of the housing and configured to contact a respective one of the plurality of contact pads.

20. The electronic system of claim 19, wherein:
the plurality of separators of the receptacle connector extend farther from the rear end of the housing than the tails of the plurality of terminals of the receptacle connector; and
the plurality of elongated openings of the circuit board extend farther from the rear end of the housing than the plurality of separators of the receptacle connector.
